(19) United States
(12) Patent Application Publication
(10) Pub. No.: US 2008/0061450 A1
(43) Pub. Date: Mar. 13, 2008

(54) Bonding wire and bond using a bonding wire

(76) Inventors: Manfred Reinold, Schwieberdingen (DE); Thomas Kaden, Schwieberdingen (DE); Immanuel Mueller, Gomaringen (DE)

Correspondence Address: KENYON & KENYON LLP, ONE BROADWAY, NEW YORK, NY, 10004, US

(21) Appl. No.: 11/810,276

(22) Filed: Jun. 4, 2007

(30) Foreign Application Priority Data
Jun. 2, 2006 (DE) 102006025868.1

(51) Int. Cl. H01L 23/49; H01B 5/00

(52) U.S. Cl. 257/784; 174/126.3; 174/133 R; 257/E23.024

(57) ABSTRACT

A bonding wire and a bond using such a bonding wire. The contour of the cross-sectional area of the bonding wire has a shape deviating from a circle shape and from a rectangle shape having two sides of different length.

### FIELD OF THE INVENTION

The present invention relates to a bonding wire for contacting two microelectronic contact surfaces, as well as a bond using such a bonding wire.

### BACKGROUND INFORMATION

Bonding wires are used chiefly to electrically connect integrated circuits, substrates, pressed screens, LEDs, etc. The main application areas of bonding wires are logic circuits, storage circuits and analog circuits, as well as HF technology. Bonding wires having a circular cross-sectional area, or rectangular cross-sectional area having two cross-sectional contour sides of different length, so-called ribbons, are used exclusively in practice. In microelectronic assembly and interconnection technology, the bonding wire is often made of gold or a gold alloy, but aluminum wires and copper wires are also used. The diameters of the bonding wires having a circular cross section in assembly and interconnection technology are between approximately 25 and 50 μm, depending upon the maximum current load to be accommodated. For example, in the case of a silicon chip, the pins visible from the outside are connected to the pads in the interior of the chip via such bonding wires. In the area of power electronics, bonding wires having a diameter between 125 μm and 500 μm are used. Wedge bonders or ball bonders are used in the bonding process. In contrast to wedge bonding, during ball bonding the end of the bonding wire is melted via an electric arc to form a spherical shape. Moreover, a capillary is used instead of a needle in the wedge bond process, which means the bonding wire is led in vertically and not at an angle. A known wedge-wedge-ultrasonic bonding device is described, for example, in PCT International Patent Publication No. WO 03/068445. In addition, combined ball-wedge methods are also used.

A disadvantage in the known bonding wires and the bonds produced by them is the frequent occurrence of breaks in the transition region between the bond foot, thus the actual contact area with the microelectronic component, and the remaining bonding wire. Given today's demands for resistance to vibration and temperature fluctuations, known bonding wires are already pushing up against their limits.

### SUMMARY OF THE INVENTION

An object of the present invention is to provide a bonding wire and a bond produced by it whose service life is increased compared to known bonding wires.

The present invention is based on the idea of not making the cross section of the bonding wire circular, and not making it rectangular having two sides of different length, like known ribbons. Due to the new type of bonding-wire geometry, it is possible to markedly increase the service life of electrical wire-bond contactings. Moreover, bonding wires may be formed differently for different applications.

Aluminum is particularly suitable as material for producing the bonding wire of the present invention, the aluminum wire being welded by a short pulse of ultrasonic energy. However, it is also conceivable to produce the bonding wire of the present invention from other metals and alloys. Furthermore, alternatively or in addition to ultrasound, the energy for the welding process may be supplied by pressure and temperature.

In refinement of the present invention, advantageously the cross-sectional area of the bonding wire is formed in the shape of a square. In particular, such bonding wires are suitable for use in power electronics, since because of the quadratic formation of the cross-sectional area, bonding wires having exceptional current carrying capacity are provided.

According to an alternative realization of the present invention, the contour of the cross-sectional area of the bonding wire is elliptical. Such bonding wires have a substantially increased service-life stability.

It is particularly advantageous if the contour of the cross-sectional area of the bonding wire is corrugated and/or serrated. The corrugated and/or serrated contour of the cross-sectional area of the bonding wire provides a flexible bonding-wire profile structure. The number and the depth of the elevations and depressions set apart in the circumferential direction may be selected differently depending on the application case. It is possible to weld the bonding wires at different locations, preferably set apart from each other in the circumferential direction, to the component to be connected. For example, the bonding wire may be welded at least two elevations, set apart in the circumferential direction, to the microelectronic component or element to be connected. As a result, it is not necessary to position a plurality of individual bonding wires side by side. A further advantage of the serrated and/or corrugated implementation of the contour of the cross-sectional area of the bonding wire is that, because of the depressions, a pulse of ultrasonic energy necessary for the welding is able to penetrate through the bonding wire up to the contact surface between the bonding wire and the component to be connected. When working with an implementation that is not corrugated and/or serrated, if the bonding wire is particularly thick, it is not possible to ensure the penetration by ultrasonic pulses. Therefore, the embodiment of the bonding wire according to the present invention makes it possible to provide particularly thick bonding wires, i.e., bonding wires having exceptional current-carrying capacity.

In refinement of the present invention, it is provided that the adjacent elevations and/or depressions in the circumferential direction of the bonding wire, resulting from the corrugated and/or serrated implementation of the contour of the cross-sectional area, are triangular or rectangular. In particular, the contour of the cross-sectional area has a comb shape.

It is conceivable for the contour of the cross-sectional area of the bonding wire to be corrugated and/or serrated over its entire periphery. It is equally possible for the contour of the cross-sectional area to be corrugated and/or serrated only at least one section, and therefore to provide a bonding wire that is serrated or corrugated only on one side.

The elevations and depressions set apart in the circumferential direction may all be formed and/or dimensioned the same or also differently.

The contour of the bonding wire already deviates from a circle shape or a rectangle shape solely by the provision of a serrated and/or corrugated contour of the cross-sectional area of the bonding wire. In further development of the present invention, it is now provided that the cross-sectional area of the bonding wire has a circular, or rectangular, or quadratic, or elliptical envelope contour. Understood by the term envelope contour is an imaginary peripheral contour of the cross-sectional area, which is obtained when the cross-sectional area is embraced in clinging fashion by a flexible element. In this case, the depressions are excluded from the envelope contour.

According to one expedient refinement of the present invention, the contour of the cross-sectional area is constant over the longitudinal extension of the bonding wire in the non-processed state of the bonding wire. Naturally, in response to the contacting of the microelectronic component to be connected, the bonding wire is partially deformed in the contact area.

### BRIEF DESCRIPTION OF THE DRAWINGS

FIG. 1 shows a plurality of bonds between a chip and a lead frame.

FIG. 2a shows a schematic representation of a bonding wire in cross section, having a quadratic cross-section profile.

FIG. 2b shows a bond between two contact surfaces using a bonding wire according to FIG. 2a having a quadratic cross-section profile.

FIG. 3a shows a schematic representation of a bonding wire in cross section, having an elliptical cross-section profile.

FIG. 3b shows a bond between two contact surfaces using a bonding wire according to FIG. 3a having an elliptical cross-section profile.

FIG. 4 shows a schematic, perspective representation of a bonding wire having a corrugated cross-section profile.

FIG. 5 shows a schematic representation of a bonding wire having a comb-like, serrated cross-section profile on one side.

FIG. 6 shows a schematic representation of a bonding wire having a serrated cross-section profile on two sides.

FIG. 7 shows a schematic representation of a bonding wire in cross section, having a star-shaped cross-section profile and a circular envelope contour.

### DETAILED DESCRIPTION

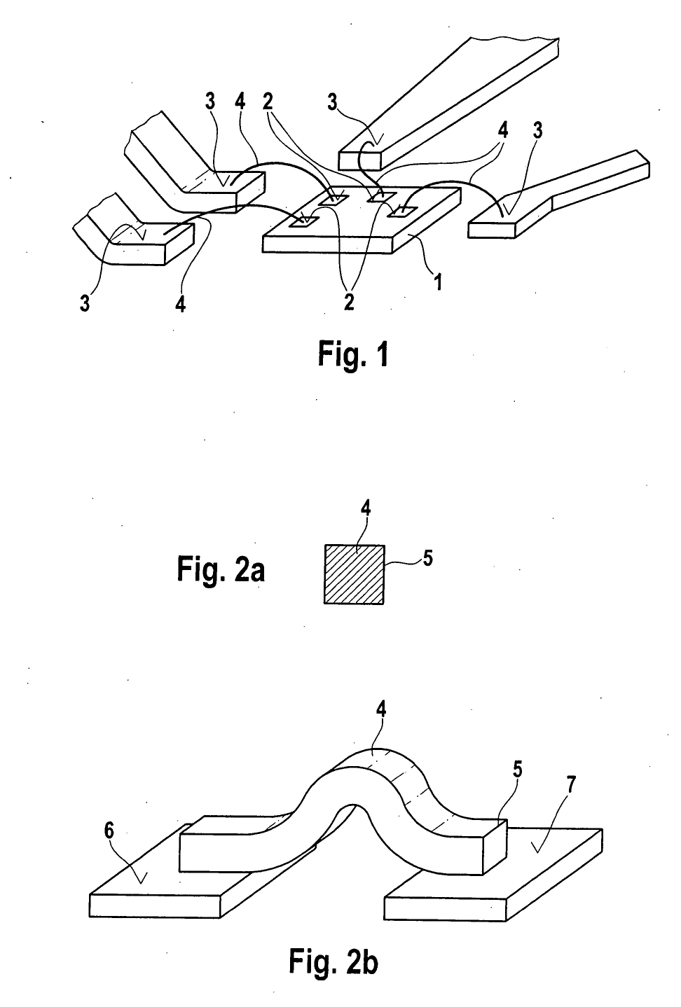

FIG. 1 shows a microchip 1 whose chip contact surfaces (pads) 2 are electroconductively connected to substrate contact surfaces 3 with the aid of bonding wires 4. Bonding wires 4 have a cross-section contour deviating from a circle shape and from a rectangle shape having four sides, of which in each case only two sides are of equal length. More flexible bonding wires 4 are thereby obtained, which are particularly stable with respect to stress due to vibration and temperature fluctuations and the changes in length associated with it, especially during the bonding process. In this exemplary embodiment, bonding wires 4 are made of aluminum and were welded to chip contact surfaces 2 and substrate contact surfaces 3 using pulses of ultrasonic energy. It is also possible to use other energy forms for the welding, and to use bonding wires made of other materials such as copper and/or palladium and/or nickel. The bonding wire of the present invention is preferably produced from aluminum, since such bonding wires are particularly suitable as bonding wires for use in power electronics.

FIG. 2a shows a bonding wire 4 in cross section. In contrast to known ribbon bonding wires, bonding wire 4 according to FIG. 2a has a quadratic contour 5 having four sides of equal length. FIG. 2b shows a bond between two set-apart contact surfaces 6, 7, e.g., two substrate surfaces. A bonding wire 4 according to FIG. 2a having a quadratic contour 5 of the cross-sectional area was used for contacting the two contact surfaces 6, 7. The contacting to contact surfaces 6, 7 is carried out using one of the sides of quadratic cross-section contour 5.

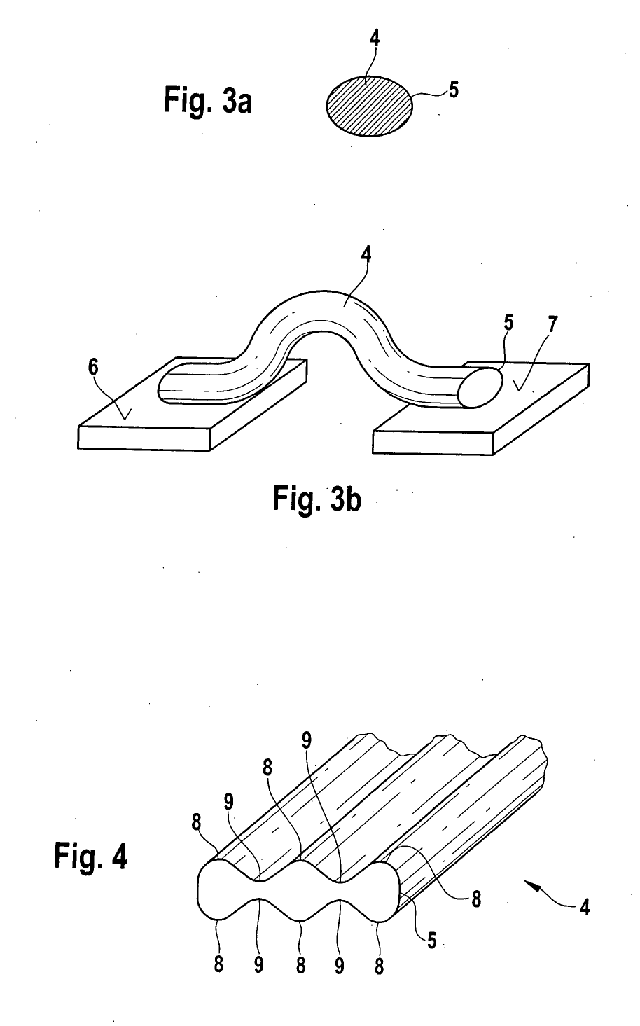

FIG. 3a shows an alternative bonding wire 4 in cross section. Elliptical contour 5 of the cross-sectional area can be recognized. FIG. 3b shows a bond between contact surfaces 6, 7, e.g., a microchip and a substrate, using a bonding wire 4 having an elliptical cross-sectional area.

FIG. 4, in a schematic perspective representation, shows a bonding wire that is corrugated in the circumferential direction. Contour 5 of the cross-sectional area, corrugated over its entire periphery, has elevations 8 and depressions 9 set apart in the circumferential direction. In this exemplary embodiment, bonding wire 4 is formed in such a way that, in each case, two depressions 9 and three elevations 8 are opposite each other. For example, bonding wire 4 shown in FIG. 4 can be joined, using all lower elevations 8 in the drawing plane, to a contact surface (not shown), so that three set-apart contact points result between the contact surface and bonding wire 4, thereby improving the flexibility of the bond. The areas having depressions 9 are able to be penetrated by a pulse of ultrasonic energy, permitting bonding wire 4 to be made thicker overall, and at the same time ensuring the possibility of using the ultrasonic welding method.

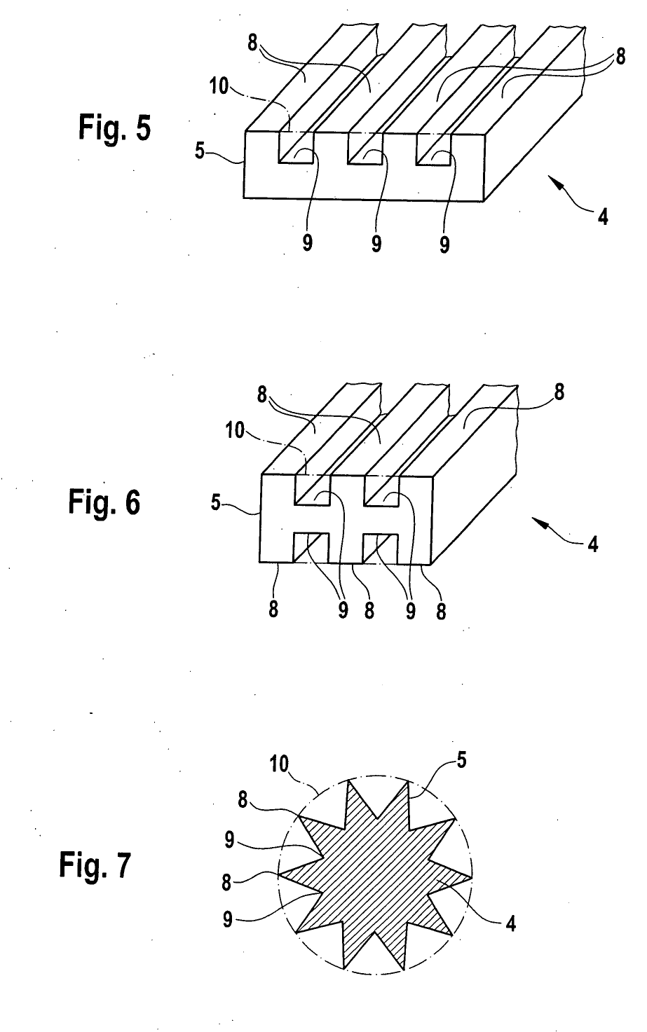

Bonding wire 4 shown in FIG. 5 has a serrated, comb-like contour 5. Compared to its rectangular envelope contour 10, three depressions 9 set apart in the circumferential direction are recessed toward the inside. This yields a contour 5 of the cross-sectional area that is serrated on one side, elevations 8 and depressions 9 being rectangular. There are two different possibilities for fixing the bonding wire, shown in FIG. 5, to a contact surface. It is conceivable to weld bonding wire 4 using the lower side in the drawing plane, thus, to weld it over a large area to an electronic component or a contact surface. In this case, depressions 9 set apart in the circumferential direction facilitate the penetration of bonding wire 4 by pulses of ultrasonic energy, since the effective thickness of bonding wire 4 is reduced in this area. Alternatively, bonding wire 4 shown in FIG. 5 may be welded, using the upper side in the drawing plane, onto a contact surface. In this case, a maximum of four, preferably set-apart contact points result in the areas of elevations 8. A particularly flexible bond is thereby obtained between bonding wire 4 and the contact surface (not shown).

Bonding wire 4 shown in FIG. 6 is realized similarly to bonding wire 4 shown in FIG. 5. Both bonding wires 4 have a rectangular envelope contour 10. Contour 5 of bonding wire 4 shown in FIG. 6 is rectangularly serrated on two opposite sides, depressions 9 of the opposite sides being directly opposite each other, which means the penetration of bonding wire 4 by pulses of ultrasonic energy is facilitated, and a thicker bonding wire 4 having greater current carrying capacity is obtained overall.

FIG. 7 shows a bonding wire 4 in cross section. Contour 5 of the cross-sectional area is star-shaped, having triangular serrations set apart in the circumferential direction. Bonding wire 4 shown in FIG. 7 has a circular envelope contour 10.

What is claimed is:

1. A bonding wire for contacting two contact surfaces, comprising:
a bonding wire element, a contour of a cross-sectional area of the bonding wire element having a shape deviating from a circle shape and from a rectangle shape having two sides of different length.

2. The bonding wire according to claim 1, wherein the contour of the cross-sectional area is formed in a shape of a square.

3. The bonding wire according to claim 1, wherein the contour of the cross-sectional area is formed in a shape of an ellipse.

4. The bonding wire according to claim 1, wherein the contour of the cross-sectional area is at least one of corrugated and serrated.

5. The bonding wire according to claim 1, wherein at least one of elevations and depressions, obtained due to at least one of a corrugated and serrated formation of the contour, have at least one of a triangular and rectangular shape.

6. The bonding wire according to claim 1, wherein the contour of the cross-sectional area is at least one of corrugated and serrated over an entire periphery.

7. The bonding wire according to claim 1, wherein the contour of the cross-sectional area is at least one of only sectionally corrugated and serrated.

8. The bonding wire according to claim 1, wherein the cross-sectional area has one of a circular, rectangular, quadratic, and elliptical envelope contour.

9. The bonding wire according to claim 1, wherein the contour of the cross-sectional area is identical at every location on the bonding wire element in a non-contacted state.

10. A bond between two contact surfaces comprising:
at least one bonding wire interconnecting the contact surfaces, a contour of a cross-sectional area of the bonding wire having a shape deviating from a circle shape and from a rectangle shape having two sides of different length.

11. The bond according to claim 10, wherein the bond is between a chip and a printed circuit trace.

12. The bond according to claim 10, wherein the bonding wire is bonded at least two locations, set apart from each other, to one of the contact surfaces.
